(19) United States
(12) Patent Application Publication
(10) Pub. No.: US 2026/0033381 A1
(43) Pub. Date: Jan. 29, 2026

(54) TRANSISTORS INCLUDING PASSIVATION MODULATION AND RELATED FABRICATION METHODS

(71) Applicant: MACOM Technology Solutions Holdings, Inc., Lowell, MA (US)

(72) Inventors: Heather Frances Barton, Durham, NC (US); Matthew Russell King, Wake Forest, NC (US)

(21) Appl. No.: 18/780,915

(22) Filed: Jul. 23, 2024

(51) Int. Cl. H01L 23/31; H01L 21/02; H01L 23/29; H01L 29/417

(52) U.S. Cl. CPC H01L 23/3171; H01L 21/0228; H01L 23/298; H10D 64/251

(57) ABSTRACT

A transistor device includes a semiconductor structure, a multi-layer passivation stack on the semiconductor structure, source and drain contacts on the semiconductor structure, and a gate on the semiconductor structure between the source and drain contacts. The multi-layer passivation stack includes a plurality of passivation layers having different electrical properties, and at least one opening extending through the passivation layers. The at least one opening exposes a surface of the semiconductor structure between the gate and the source or drain contact.

### FIELD

The present disclosure relates to semiconductor devices, and more particularly, to transistor devices and related fabrication methods.

### BACKGROUND

Semiconductor materials such as silicon (Si) and gallium arsenide (GaAs) have found wide application in semiconductor devices for low power and, in the case of Si, low frequency applications. However, these materials may not be well-suited for high power and/or high frequency applications, for example, due to their relatively small bandgaps (1.12 eV for Si and 1.42 for GaAs at room temperature) and relatively small breakdown voltages.

For high power, high temperature and/or high frequency applications and devices, wide bandgap semiconductor materials may be used, such as silicon carbide (SiC) (e.g., with a bandgap of about 3.2 eV for 4H-SiC at room temperature) and the Group III nitrides (e.g., with a bandgap of about 3.36 eV for gallium nitride (GaN) at room temperature). These materials may have higher electric field breakdown strengths and higher electron saturation velocities as compared to GaAs and Si.

A device of particular interest for high power and/or high frequency applications is the high electron mobility transistor (HEMT), which is also known as a modulation doped field effect transistor (MODFET). In a HEMT device, a two-dimensional electron gas (2DEG) may be formed at the heterojunction of two semiconductor materials with different bandgap energies. The smaller bandgap material may have a higher electron affinity than the wider bandgap material. The 2DEG is an accumulation layer in the undoped smaller bandgap material and can contain a relatively high sheet electron concentration, for example, in excess of 10¹³ carriers/cm². Additionally, electrons that originate in the wider bandgap semiconductor may transfer to the 2DEG, allowing a relatively high electron mobility due to reduced ionized impurity scattering. This combination of relatively high carrier concentration and carrier mobility can give the HEMT a relatively large transconductance and may provide performance advantages over metal-oxide-semiconductor field effect transistors (MOSFETS) for high-frequency applications

HEMTs fabricated in Group III-nitride-based semiconductor structures (such as the gallium nitride/aluminum gallium nitride (GaN/AlGaN) material system) can generate large amounts of radio frequency (RF) power due to a combination of material characteristics, such as relatively high breakdown fields, relatively wide bandgaps, relatively large conduction band offset, and/or relatively high saturated electron drift velocity. Thus, HEMT devices may be used in RF power amplifiers. Group III-nitride-based HEMTs also offer high charge density, high electron mobility and improved thermal conductivity, particularly on SiC substrates.

Electron trapping and resulting differences between DC and RF characteristics can be a limiting factor in the performance of these devices. Silicon nitride (SiN) passivation has been employed to alleviate this trapping problem, and may provide high performance devices with power densities over 10 W/mm at 10 GHz. For example, U.S. Pat. No. 6,586,781 to Wu et al. describes methods and structures for reducing trapping effects in GaN-based transistors. However, due to the high electric fields existing in these structures, charge trapping can still be of concern.

### SUMMARY

According to some embodiments of the present disclosure, a transistor device includes a semiconductor structure, a multi-layer passivation stack on the semiconductor structure, source and drain contacts on the semiconductor structure, and a gate on the semiconductor structure between the source and drain contacts. The multi-layer passivation stack includes a plurality of passivation layers having different electrical properties, and at least one opening extending through the passivation layers. The at least one opening exposes a surface of the semiconductor structure between the gate and the source or drain contact.

In some embodiments, the passivation layers may include respective point defects, dielectric constants, refractive indices, and/or material compositions that differ from one another.

In some embodiments, ones of the passivation layers that are closer to the surface of the semiconductor structure may have a higher dielectric constant than ones of the passivation layers that are farther from the surface.

In some embodiments, ones of the passivation layers that are closer to the surface of the semiconductor structure may have a higher silicon content than ones of the passivation layers that are farther from the surface.

In some embodiments, the passivation layers of the multi-layer passivation stack may include a first passivation layer on a first region of the semiconductor structure adjacent the gate. A second passivation layer may extend into the at least one opening in the multi-layer passivation stack and onto the surface in a second region of the semiconductor structure between the first region and the drain contact. The first and second passivation layers may have different electrical properties and extend along respective interfaces with the first and second regions.

In some embodiments, the respective interfaces may extend along a drain access region of the semiconductor structure between the gate and the drain contact.

In some embodiments, a first dielectric constant of the first passivation layer may be greater than a second dielectric constant of the second passivation layer.

In some embodiments, the first passivation layer and the second passivation layer may include silicon, and a first silicon content of the first passivation layer may be greater than a second silicon content of the second passivation layer.

In some embodiments, the second passivation layer may be a sublayer of a second multi-layer passivation stack.

In some embodiments, a source access region of the semiconductor structure between the gate and the source contact may be free of an interface with the second passivation layer.

In some embodiments, the semiconductor structure may include a channel layer and a barrier layer defining a heterojunction therebetween.

According to some embodiments of the present disclosure, a transistor device may include a semiconductor structure, source and drain contacts on the semiconductor structure, a gate on the semiconductor structure between the source and drain contacts, and first and second passivation layers on a surface of the semiconductor structure between the gate and the source or drain contact. The first and second passivation layers have different electrical properties and extending along respective interfaces with the semiconductor structure.

In some embodiments, the first passivation layer may be on a first region of the surface adjacent the gate and may include at least one opening therein that exposes a second region of the surface, and the second passivation layer may extend into the at least one opening and onto the second region.

In some embodiments, the first and second passivation layers may include respective point defects, dielectric constants, refractive indices, and/or material compositions that differ from one another.

In some embodiments, a first dielectric constant of the first passivation layer may be higher than a second dielectric constant of the second passivation layer.

In some embodiments, at least one of the first passivation layer or the second passivation layer may be a sublayer of a multi-layer passivation stack comprising a plurality of stacked passivation layers having different electrical properties.

In some embodiments, ones of the stacked passivation layers that are closer to the surface of the semiconductor structure may have a higher dielectric constant than ones of the stacked passivation layers that are farther from the surface.

In some embodiments, ones of the stacked passivation layers that are closer to the surface of the semiconductor structure may have a higher silicon content than ones of the stacked passivation layers that are farther from the surface.

In some embodiments, the respective interfaces may extend along a drain access region of the semiconductor structure between the gate and the drain contact.

In some embodiments, a source access region of the semiconductor structure between the gate and the source contact may be free of an interface with the second passivation layer.

According to some embodiments of the present disclosure, a method of fabricating a transistor device includes forming a multi-layer passivation stack on a semiconductor structure, the multi-layer passivation stack comprising a plurality of passivation layers having different electrical properties, forming source and drain contacts on the semiconductor structure, forming a gate opening in the multi-layer passivation stack, and forming at least one additional opening in the multi-layer passivation stack that exposes a surface of the semiconductor structure between the gate opening and the source or drain contact.

In some embodiments, the passivation layers may include respective point defects, dielectric constants, refractive indices, and/or material compositions that differ from one another.

In some embodiments, ones of the passivation layers that are closer to the surface of the semiconductor structure may have a higher dielectric constant than ones of the passivation layers that are farther from the surface.

In some embodiments, ones of the passivation layers that are closer to the surface of the semiconductor structure may have a higher silicon content than ones of the passivation layers that are farther from the surface.

In some embodiments, forming the multi-layer passivation stack may include forming a first passivation layer of the plurality of passivation layers on the surface of the semiconductor structure using a chemical vapor deposition process, and forming at least one subsequent passivation layer of the plurality of passivation layers using a physical vapor deposition process.

In some embodiments, the passivation layers of the multi-layer passivation stack may include a first passivation layer on a first region of the semiconductor structure adjacent the gate opening. The method may further include forming a second passivation layer that extends into the at least one additional opening in the multi-layer passivation stack and onto the surface in a second region of the semiconductor structure between the first region and the source or drain contact. The first and second passivation layers may have different electrical properties and may extend along respective interfaces with the first and second regions.

In some embodiments, the respective interfaces may extend along a drain access region of the semiconductor structure between the gate opening and the drain contact.

In some embodiments, a source access region of the semiconductor structure between the gate opening and the source contact may be free of an interface with the second passivation layer.

In some embodiments, forming the second passivation layers may be performed using a chemical vapor deposition process.

In some embodiments, a first dielectric constant of the first passivation layer may be greater than a second dielectric constant of the second passivation layer.

In some embodiments, the first passivation layer and the second passivation layer may include silicon, and a first silicon content of the first passivation layer may be greater than a second silicon content of the second passivation layer.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the present disclosure, and be protected by the accompanying claims.

### BRIEF DESCRIPTION OF THE DRAWINGS

FIG. 1 is a schematic cross-sectional view of a transistor structure including passivation layers according to some embodiments of the present disclosure.

FIG. 2 is an enlarged view of the transistor device of FIG. 1.

FIGS. 3A, 3B, 3C, 3D, 3E, and 3F are schematic cross-sectional views illustrating example intermediate fabrication steps in methods for fabricating transistor structures including passivation layers according to some embodiments of the present disclosure.

FIG. 4 is a flowchart illustrating methods of fabricating transistor structures including passivation layers in accordance with some embodiments of the present disclosure.

FIG. 5 is a table illustrating performance benefits of transistor structures including passivation layers according to some embodiments of the present disclosure.

FIG. 6 is a schematic plan view of a transistor die according to embodiments of the present disclosure that illustrates metallization on a surface of the semiconductor structure thereof.

### DETAILED DESCRIPTION OF EMBODIMENTS

Some embodiments of the inventive concepts may arise from realization that characteristics of passivation layers (such as dielectric constant, film composition, and point defects) can significantly affect performance of a semiconductor device. For example, increasing the silicon content of the passivation layer(s) may reduce charge trapping at the surface of the semiconductor structure, but may negatively affect other device characteristics (e.g., by increasing current leakage and/or capacitance).

Embodiments of the inventive concepts provide multi-layer passivation stacks including passivation layers (also referred to herein as passivation sublayers) having different characteristics, such that the electrical properties of the passivation stack vary along the interface with the semiconductor structure (also referred to as the passivation-semiconductor interface) and/or with distance from the surface of the semiconductor structure. For example, the passivation stack may include multiple passivation sublayers having different electrical properties along respective interfaces with the semiconductor structure (e.g., along the contact areas between the passivation layers and the barrier layer of a HEMT), and/or may include a gradient in passivation sublayer electrical properties with distance from the semiconductor structure (e.g., such that passivation layers having a higher dielectric constant are closer to the barrier layer of the HEMT). Modulation of passivation layer electrical properties as described herein can reduce charge trapping and provide faster transient response or recovery time, without increasing leakage or capacitance.

The electrical properties of the passivation layers may be modulated compositionally (for example, using different process parameters and/or deposition methods to form the passivation layers with different characteristics) and/or structurally (for example, by forming an opening or discontinuity in one or more of the passivation layers). In particular, charge trapping can be reduced or minimized by increasing the silicon content (i.e., with respect to composition ratio) of the passivation layers that are closer to or in direct contact with a surface of the semiconductor structure (in comparison to the silicon content of passivation layers that are farther from the surface), and/or by using a CVD process (rather than a PVD process) to deposit one or more of the passivation layers directly on the surface of the semiconductor structure. Layers in the passivation stack that are farther from the semiconductor surface may have decreasing silicon content and/or may be formed by PVD. In addition, leakage current and/or capacitance can be reduced or minimized by providing at least one structural opening or discontinuity in the passivation layer(s). For instance, an additional opening or trench (in addition to the gate trench) may be formed in a comparatively high silicon content or CVD-based initial passivation layer to create a discontinuity therein that exposes a portion of the surface of the semiconductor structure between the gate and the drain or source, and a second or subsequent passivation layer may be provided in the opening.

Without being bound by theory, the deposition of a high-silicon content or CVD-based first/initial passivation layer may provide a path or mechanism for trap dissipation (thereby reducing charge trapping and providing faster transient response or recovery time). In particular, the higher silicon content passivation layer may provide a high source of donor electrons, which may fill surface traps such that they become neutral and do not capture barrier layer electrons during operation. This benefit may come at the expense of greater current leakage and/or increased capacitance (e.g., gate-to-drain capacitance, Cgd), for example, due to higher dielectric constant of the passivation layer. However, the removal of portions of the initial passivation layer to create one or more openings or discontinuities that expose portions of the semiconductor surface (into which one or more second/subsequent passivation layers may be deposited to contact the exposed portions of the semiconductor surface) may reduce the negative effects on current leakage and capacitance, while maintaining the improvements in charge trapping recovery time provided by the high silicon content initial passivation layer.

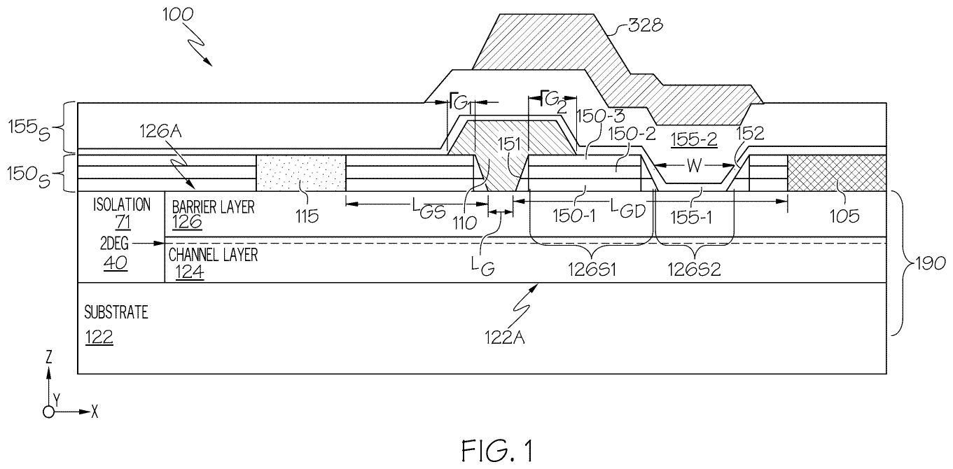

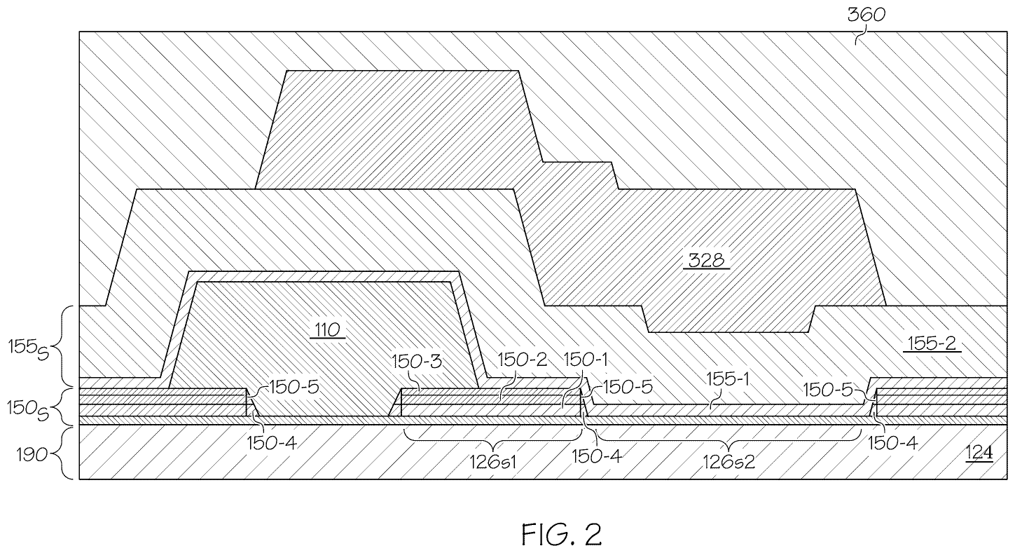

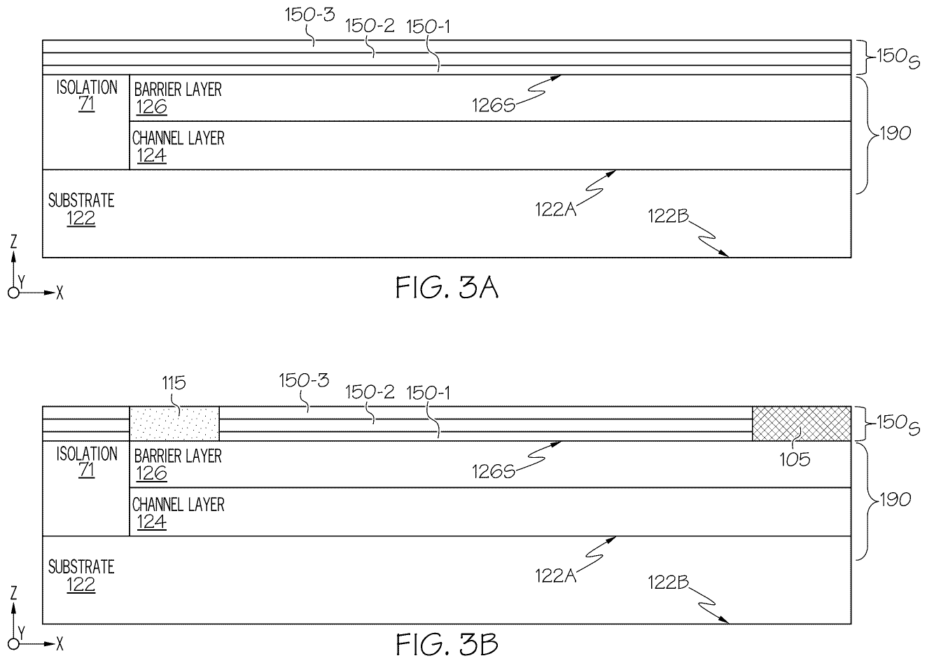

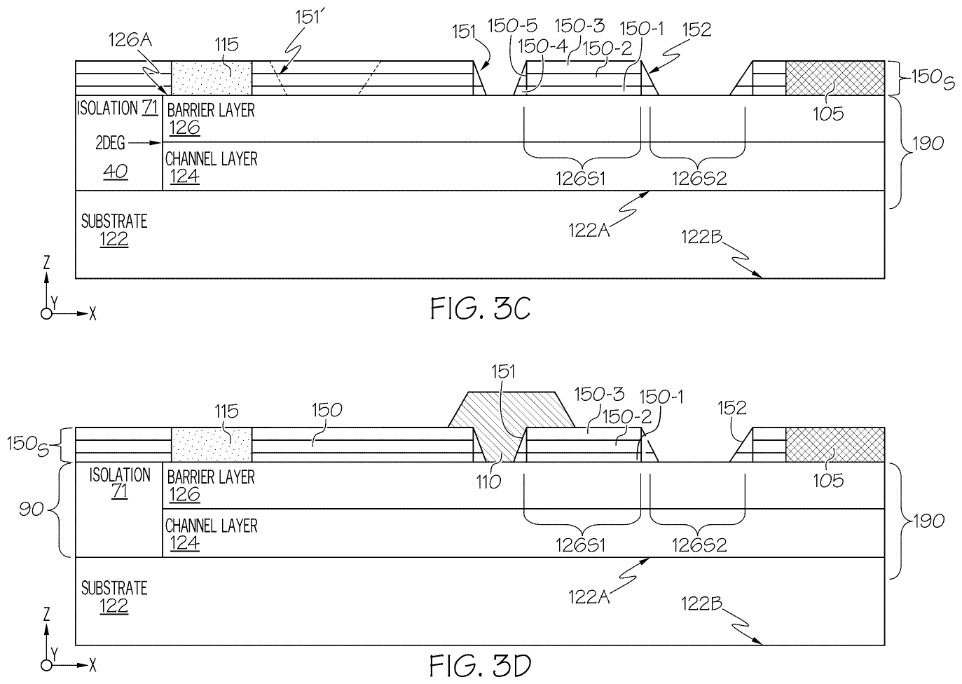

FIG. 1 is a schematic cross-sectional view of a transistor device including passivation layers according to some embodiments of the present disclosure, illustrated by way of example with reference to unit cell transistor structure 100 (also referred to herein as a transistor structure or transistor cell) of a transistor device. FIG. 2 is an enlarged view of the transistor device of FIG. 1, illustrating a portion of the semiconductor structure between the gate and the drain contact, also referred to as the drain access region. In particular, FIGS. 1 and 2 illustrate a HEMT device including modulated passivation layer stacks as described herein.

As shown in FIGS. 1 and 2, a transistor structure 100 is formed on a substrate 122 such as, for example, a silicon carbide substrate. Hundreds or thousands of unit cell transistor structures 100 may be formed on the semiconductor substrate 122, and may be electrically connected (e.g., in parallel) to provide the HEMT device. The substrate 122 may be a semi-insulating silicon carbide substrate that may be, for example, the 4H polytype of silicon carbide. Other silicon carbide candidate polytypes may include the 3C, 6H, and 15R polytypes. Although silicon carbide may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 122 may be a silicon carbide wafer, and the HEMT device may be formed, at least in part, via wafer-level processing, and the wafer may then be diced or otherwise singulated to provide a die including a plurality of the unit cell transistor structures 100.

The transistor structure 100 includes a channel layer 124 on the substrate 122, and a barrier layer 126 on the channel layer 124 opposite the substrate 122. Source and drain electrodes (also referred to herein as source and drain contacts) 115 and 105 are formed on an upper surface of the barrier layer 126 and are laterally (e.g., along the X-direction) spaced apart from each other. The source contact 115 and the drain contact 105 may form an ohmic contact to the barrier layer 126.

One or more insulator layers (for example, a first passivation layer stack 150s and a second passivation layer stack 155s) are formed on the barrier layer, and a gate contact (or simply “gate”) 110 is formed on a surface of the barrier layer 126 between the source and drain electrodes 115 and 105. Depending on configuration, one or more of the passivation layers 150, 155 may be formed before and/or after formation of the gate 110.

The channel layer 124 may have a bandgap that is less than the bandgap of the barrier layer 126 and the channel layer 124 may also have a larger electron affinity than the barrier layer 126. The channel layer 124 and barrier layer 126 may together define a semiconductor structure 190. The term “semiconductor structure” refers to a structure that includes one or more semiconductor materials, such as semiconductor substrates and/or semiconductor epitaxial layers. In the illustrated examples, the semiconductor structure 190 may be a semiconductor layer structure including one or more layers formed by epitaxial growth, and thus include one or more epitaxial layers 124, 126.

In the illustrated HEMT devices, the semiconductor layer structure 190 may be Group-III nitride based, although other material systems can also be used. Group III nitrides may refer to semiconductor compounds formed between nitrogen and the elements in the Group III of the periodic table, such as aluminum (Al), gallium (Ga), and/or indium (In) to form binary (e.g., GaN), ternary (e.g., AlGaN, AlInN), and quaternary (e.g., AlInGaN) compounds. Accordingly, formulas such as AlₓGa₁₋ₓN, where 0≤x≤1, may be used to describe these compounds. One or both of the channel layer 124 and the barrier layer 126 may include sub-layers including doped or undoped (i.e., “unintentionally doped”) layers of Group III-nitride materials, including material compositions which may be stepwise or continuously graded. For example, the channel layer 124 may be a multi-layer structure, such as a superlattice or combinations of GaN, AlGaN or the like. The channel layer 124 may be under compressive strain in some embodiments. In some embodiments, the barrier layer 126 may be AlN, AlInN, AlGaN, AlInGaN, AlScN, alloys thereof, or any combinations of layers thereof. The barrier layer 126 may comprise a single layer or may be a multi-layer structure. In particular embodiments of the present disclosure, the barrier layer 126 may be thick enough and may have a high enough aluminum (Al) composition and doping to induce a significant carrier concentration at the interface between the channel layer 124 and the barrier layer 126 through polarization effects when the barrier layer 126 is buried under ohmic contact metal.

While semiconductor structure 190 is shown with reference to epitaxial layers 124, 126 for purposes of illustration, the semiconductor structure 190 may include additional layers/structures/elements such as isolation layer(s) 71, buffer and/or nucleation layer(s) on or between substrate 122 and the one or more epitaxial layers 124, and/or a cap layer on an upper surface 126A of the epitaxial layer 126. For example, an AIN buffer layer may be formed on the upper surface 122A of the substrate 122 to provide an appropriate crystal structure transition between the silicon carbide substrate 122 and the remainder of the layers of the semiconductor structure 190. The optional buffer/nucleation/transition layers, as well as the channel layer 124 and/or the barrier layer 126, may be deposited by metal-organic chemical vapor deposition (MOCVD), molecular beam epitaxy (MBE), and/or hydride vapor phase epitaxy (HVPE).

The material of the gate 110 may be chosen based on the composition of the semiconductor structure 190, and may, in some embodiments, be a Schottky contact. Some materials capable of making a Schottky contact to a Group III nitride based semiconductor material that may be used as the gate 110 may include, for example, nickel (Ni), platinum (Pt), ruthenium (Ru), nickel silicide (NiSiₓ), copper (Cu), palladium (Pd), chromium (Cr), tungsten (W) and/or tungsten silicon nitride (WSiN).

The source contact 115 and/or the drain contact 105 may include a metal that can form an ohmic contact to a Group III nitride based semiconductor material. Suitable metals may include refractory metals, such as Ti, W, titanium tungsten (TiW), silicon (Si), titanium tungsten nitride (TiWN), tungsten silicide (WSi), rhenium (Re), Niobium (Nb), Ni, gold (Au), aluminum (Al), tantalum (Ta), molybdenum (Mo), NiSiₓ, titanium silicide (TiSi), titanium nitride (TiN), WSiN, Pt and the like. Thus, the source contact 115 and/or the drain contact 105 may contain an ohmic contact portion in direct contact with the layer 126. In some embodiments, the source contact 115 and/or the drain contact 105 may be ohmic contacts.

In operation, a two-dimensional electron gas (2DEG) layer 40 may be formed at a junction between the channel layer 124 and the barrier layer 126 when the HEMT device is biased to be in its conducting or “on” state. The 2DEG layer 40 acts as a highly conductive channel that allows current to flow between the source and drain regions that are beneath the source contact 115 and the drain contact 105, respectively. In particular, the channel layer 124 and the barrier layer 126 of the semiconductor structure 190 may be formed of materials having different bandgaps, such that a heterojunction is defined at an interface between the channel layer 124 and the barrier layer 126. In some embodiments, the substrate 122 includes silicon carbide, the channel layer 124 includes GaN, and the barrier layer 126 includes AlGaN. The 2DEG conduction channel 40 can be induced at the heterointerface between the channel layer 124 and the barrier layer 126. The channel layer 124, 2DEG conduction channel 40 and barrier layer 126 can generally form the active region of the HEMT device. It should be noted that while described herein primarily with reference to fabrication and structures of HEMT devices, the elements and concepts of embodiments described herein can be applied to many different types of transistor structures.

As noted above, improved performance can be achieved in accordance with some embodiments of the present disclosure by modulating electrical properties of multi-layer passivation stacks (for example, by varying material composition and/or fabrication processes), such that passivation layers with different characteristics are formed or otherwise provided with respective interfaces along the contact area between the passivation layer(s) 150, 155 and the barrier layer 126, and/or at respective distances from the barrier layer 126. The first and second passivation layer stacks 150s and 155s may include passivation layers 150-1, 150-2, 150-3 (collectively 150) and 155-1, 155-2 (collectively 155), respectively. The passivation layers 150 and 155 of each of the first and second passivation layer stacks 150s and 155s may differ, for example, with respect to physical characteristics (e.g., point defects, refractive indices), electrical characteristics (e.g., dielectric constant), and/or material characteristics or composition (e.g., silicon content). The second (e.g., subsequently formed) passivation layer(s) 155 may likewise differ from the first (e.g., initially formed) passivation layer(s) 150. For example, the passivation layers 150 and/or 155 may be silicon nitride-based, and respective passivation layers can be deposited by different methods, including physical or chemical vapor deposition, and can also vary in composition ratio of silicon to nitrogen (denoted herein as Si:N). Device patterning can be used to form one or more recesses, trenches, or other discontinuities (collectively referred to as openings) 152 in the first or initial SiN layers 150, and allow the second or subsequent SiN layers 155 to contact the surface 126S of epitaxial layer 126 of the semiconductor structure 190, as shown in the enlarged view of FIG. 2. The silicon content of the passivation layer(s) 150, 155 may be correlated with the refractive index (RI) of the layers 150, 155, where the RI of the passivation layer(s) may increase with increased silicon content.

As shown in FIGS. 1 and 2, multiple passivation layers (in particular, a first passivation layer 150-1 and a second passivation layer 155-1) having different electrical properties are formed directly on the surface 126S of the semiconductor structure 190, extending along respective interfaces 126S1 and 126S2 therebetween. The first passivation layer 150-1 is provided on a first region 126S1 of the surface 126S adjacent the gate 110 and includes at least one opening 152 therein that exposes a second region 126S2 of the surface 126S, and the second passivation layer 155-1 extends into (e.g., conformally along or filling) the opening(s) 152 and onto the second region 126S2. The first and second passivation layers 150-1, 155-1 may have respective point defects, dielectric constants, refractive indices, and/or material compositions that differ from one another, which may provide the differing electrical characteristics. For example, a first dielectric constant of the first passivation layer 150-1 may be higher than a second dielectric constant of the second passivation layer 155-1. As such, the first passivation layer 150-1 may provide increased capacitance in comparison to the second passivation layer 155-1.

In some embodiments, the first and second passivation layers 150-1 and 155-1 may be formed from silicon-based dielectric materials, such as SiₓN_{z}, SiₓC_{w}N₂, SiₓO_{y}N_{z}, or SiₓO_{y} (where the silicon content is indicated by x, and other material content is indicated by w, y, and/or z). The first passivation layer 150-1 (which is directly on the first region 126S1) may have a higher silicon content than the second passivation layer 155-1 (which is directly on the second region 126S2), influencing their respective dielectric constants and/or refractive indices. In particular, a first dielectric constant and/or refractive index of the first passivation layer 150-1 may be higher than a second dielectric constant and/or refractive index of the second passivation layer 155-1

In addition, at least one of the multi-layer passivation stacks 150s, 155s, may include multiple sublayers 150-1 to 150-3 or 155-1 to 155-2 with varying electrical properties. For example, passivation layers 150-1 and 155-1 closer to the surface 126S of the semiconductor structure 190 may have higher dielectric constants (e.g., via higher silicon content) compared to passivation layers 150-2, 150-3 and 155-2 farther away from the surface 126S. As shown in FIG. 2, additional passivation layers 150-4 and 150-5 may also be provided on opposing sidewalls of the gate opening 151, as sidewall spacers.

The higher dielectric constant passivation layers 150-1 and/or 155-1 may be provided directly on the surface 126S of the semiconductor structure 190 to dissipate charge traps, while the lower dielectric constant passivation layers 150-2, 150-3, and 155-2 may be stacked on the higher dielectric constant passivation layers 150-1 and 155-1 and thereby spaced apart from the surface 126S). For example, passivation layers closer to the epi surface 126S (e.g., 150-1, 155-1) may have comparably higher silicon content than subsequent passivation layers (e.g., 150-2, 150-3, 150-5, and 155-2) that are stacked thereon. Within each stack 150s and 155s, successively formed sublayers 150-2, 150-3 and 155-2 may define a gradient in silicon content in comparison to initially formed sublayers 150-1 and 155-1.

In some embodiments, the comparatively higher silicon in the first passivation layer 150-1 may be sufficient to reduce charge trapping and recovery time, independent of the presence of the additional opening(s) or other discontinuities 152 therein. However, as increasing the silicon content of the first passivation layer 150-1 may result in increased leakage and capacitance, the additional opening(s) 152 the first passivation layer 150-1 may mitigate these negative effects.

In some instances, increasing the silicon content in the second passivation layer 155-1 (in comparison to that of the first passivation layer 150-1) may oppositely affect charge trapping and capacitance. Likewise, providing passivation layers with higher silicon content spaced apart from the semiconductor surface 126S (e.g., by one or more lower silicon content passivation layers) may negatively affect charge trapping and recovery time. For example, increasing the silicon content of passivation layers 150-2 and 150-3 or 155-1 (without the presence of the additional opening 152) may result in increased charge trapping and decreased capacitance. Also, increasing the silicon content of the second passivation layer 155-1 (in combination with the additional opening or discontinuity 152 in the first passivation layer 150-1), may provide conventional trapping performance, but with increased capacitance. As such, the silicon content (or RI) of the second passivation layer 155-1 may be less than that of the first passivation layer 150-1, as providing the second passivation layer 155-1 1 in the opening 152 with higher silicon content or RI than the first passivation layer 150-may have negative effects. More generally, the first and second passivation layers 150-1 and 155-1 may have the same or different compositions, while in some embodiments the silicon content, RI, or dielectric constant of the second passivation layer 155-1 may be less than that of the first passivation layer 150-1 to provide performance benefits.

While illustrated primarily with reference to forming a discontinuity or opening 152 in the initial passivation layer stack 150s between the gate and drain (also referred to as the drain access region), it will be understood that embodiments of the inventive concepts are not limited to providing the opening 152 in the specific location shown, and may include multiple discontinuities or openings 152 (of similar or varying dimensions) between the gate and drain. In some embodiments, the opening(s) 152 in the first passivation layer 150-1 (or extending through the first passivation stack 150s) may (respectively or collectively) expose about one-half to about two-thirds of the surface 126S in source or drain access region, as measured between the gate 110 and the source 115 or drain 105. For example, the openings 152 may have respective or collective dimensions of about 0.5 μm to about 0.8 μm (for example, 0.6 μm to 0.7 μm) along the surface 126S. In some embodiments, multiple openings 152 may have collective dimensions (and may provide similar performance benefits) as a single opening 152 of the same total length. That is, the dimensions of the opening(s) 152 may be beneficial for trapping so long as the opening(s) span the region of increased or elevated electric field. The areas of elevated electric field (e.g., in the drain access region) may increase with drain voltage and/or more stressed operating conditions. The length of the opening(s) 152 (as measured between the gate 110 and the source 115 or drain 105) may be less than the length of the field plate 328, for capacitance reasons. Also, the dimensions of the opening(s) 152 may also depend on the lengths (or overhang) of the gate extensions 110-1 or 110-2, as providing the opening(s) 152 too close to the gate 110 may result in manufacturing issues (e.g., due to possible deposition of the gate metal into the opening(s) 152). More generally, however, the dimension(s) and location(s) of the opening(s) 152 between the gate 110 and the source or drain may vary along the interface(s) between the first passivation layer 150-1 and the semiconductor surface 126S in accordance with embodiments described herein.

In the examples of FIGS. 1 and 2, the respective interfaces 126S1, 126S2 are provided in the drain access region of the semiconductor structure 190, while a surface 126S of the semiconductor structure 190 in the source access region is free of an interface with the second passivation layer 155-1, but embodiments of the present disclosure are not limited thereto. That is, while illustrated primarily with reference to providing the discontinuities or openings 152 in the initial passivation stack 150s in the drain access region between the gate 110 and the drain contact 105, discontinuities or openings 152 may be similarly provided in the initial passivation layer 150s in the source access region between the gate 110 and the source contact 115. Such a source side opening 152 may have lesser performance impact, however, as charge trapping may typically be concentrated in peak electric field regions of the device, which may be too far removed from the source side contact 115.

FIGS. 1 and 2 also illustrate that a field plate 328 may be formed on and spaced apart from the gate 110 by the second passivation layer stack 155s, such that the second passivation layer stack 155s provides an inter-field plate passivation layer (IFPP). The field plate 328 laterally extends toward the drain contact 105 on the drain side of the structure 100, and may be electrically connected to the gate 110 (by a connection outside the active region of the transistor structure 100). This configuration can result in a reduction of the electric field on the gate-to-drain side of the transistor structure 100. The extension distance of the field plate 328 beyond the gate 110 may affect the gate-to-source capacitance and the breakdown voltage of the device, which may impact the voltage rating and switching speed of the device. In some embodiments, the field plate 328 may be electrically connected to the source contact 115, which may affect the gate-to-drain capacitance (C_{gd}) so as to enhance the gain and/or improve linearity of the device. The field plate 328 may be implemented on the second passivation layer stack 155s in various configurations in accordance with embodiments of the present disclosure, shown in FIGS. 1 and 2 as conformally extending along the second passivation layer stack 155s over a portion of the gate 110, so as to partially overlap with the gate 110 in the vertical (e.g., Z-) direction. The field plate 328 may thus include first and second step portions at closer and farther distances or spacings from the conduction channel 40, which may allow for reduction of C_{gd} and trapping effects, as well as reduction in peak electric field proximate the drain contact 105. However, it will be understood that the field plate 328 may have various other configurations, for example, so as not to extend over the gate 110 and/or so as to be laterally spaced apart from the gate 110 by portions of the second passivation layer stack 155s (i.e., so as to be free of overlap with the gate 110 in the vertical direction).

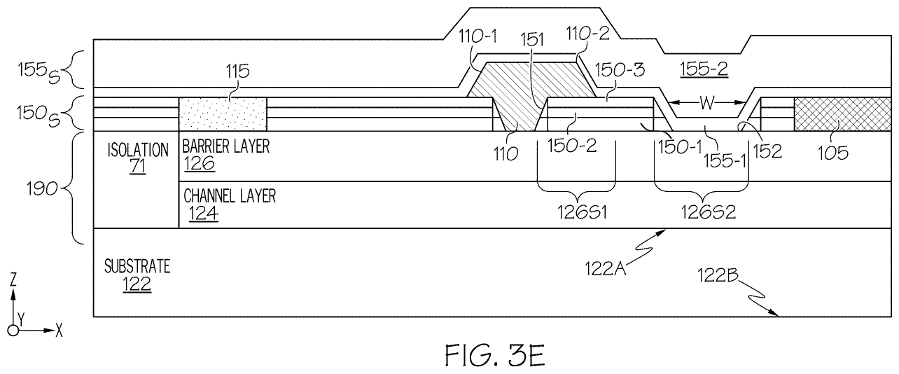

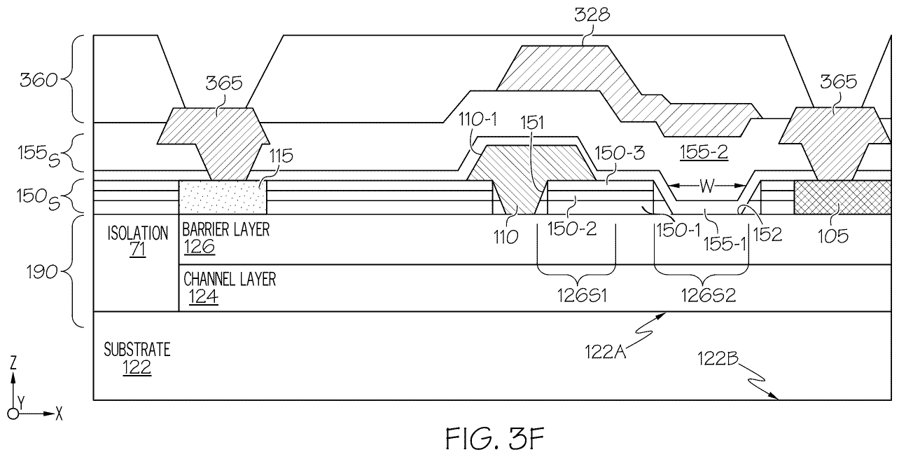

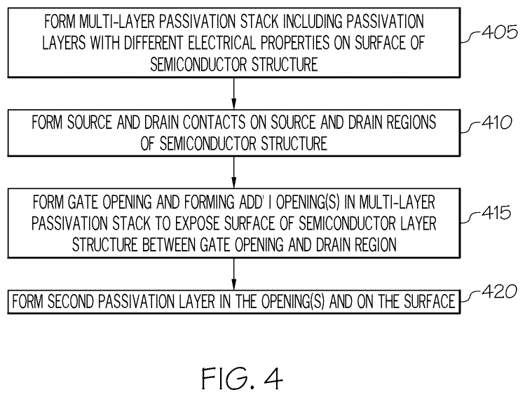

FIGS. 3A, 3B, 3C, 3D, 3E, and 3F are schematic cross-sectional views illustrating example intermediate fabrication steps in methods for fabricating transistor structures including passivation layers according to some embodiments of the present disclosure. FIG. 4 is a flowchart illustrating methods of fabricating transistor structures including passivation layers in accordance with some embodiments of the present disclosure.

As shown in FIG. 3A and FIG. 4, a multi-layer passivation stack 150s is formed on a semiconductor structure 190 (block 405). As noted above, the semiconductor structure 190 may define one of a plurality of unit cell structures 100 on the substrate 122. The substrate 122 may include silicon carbide, sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), or other materials, which may be capable of supporting growth of Group III-nitride materials. As an example, silicon carbide may have a closer crystal lattice match to Group III than sapphire, and may allow for formation of higher-quality Group III nitride films thereon. Silicon carbide also has a very high thermal conductivity, such that the total output power of Group III nitride devices on silicon carbide may not be as limited by the thermal dissipation of the substrate (as may be the case with some devices formed on sapphire). However, embodiments of the present disclosure are not limited to silicon carbide, and may utilize any suitable material for the substrate 122.

In the illustrated embodiments, the semiconductor structure 190 includes a channel layer 124 and a barrier layer 126. The channel layer 124 and/or the barrier layer may be deposited on the substrate 122 using buffer layers, transition layers, and/or nucleation layers as described above. The channel layer 124 and the barrier layer 126 may be formed of materials having different bandgaps (e.g., GaN and AlGaN, respectively) so as to define a heterojunction of a HEMT device, but embodiments of the present disclosure are not limited thereto. In some embodiments, the channel layer 124 and the barrier layer 126 may have different lattice constants, for example, with a smaller lattice constant for the relatively thin barrier layer 126 such that the barrier layer 126 “stretches” at the interface between the channel layer 124 and the barrier layer 126. Accordingly, a pseudomorphic HEMT (pHEMT) device may be provided.

The multi-layer passivation stack 150s (also referred to as a first passivation layer stack 150s) includes a plurality of passivation layers 150-1, 150-2, 150-3 having different electrical properties. The passivation layers 150-1, 150-2, 150-3 may be formed of different materials and/or using different deposition processes, so as to have respective point defects, dielectric constants, refractive indices, and/or material compositions that differ from one another. For example, the first passivation layer 150-1 may be formed on the surface 126S of the semiconductor structure 190 using a chemical vapor deposition (CVD) process and/or may have a comparatively higher dielectric constant in comparison to subsequently formed passivation layers 150-2, 150-3. The respective electrical properties of the passivation layers 150-1, 150-2, 150-3 may sequentially differ with distance from the semiconductor surface 126S in some embodiments.

For example, the first passivation layer 150-1 may be silicon nitride-or silicon oxide-based (e.g., SiₓN_{z}, SiₓC_{w}N_{z}, SiₓO_{y}N_{z}, or SiₓO_{y}, where the silicon content is indicated by x). Deposition of a high silicon content or CVD-based initial passivation layer 150-1 may provide a path or mechanism for charge trap dissipation at the surface 126S of the semiconductor structure 190. The subsequently formed passivation layers 150-2, 150-3 may be deposited using a physical vapor deposition (PVD) process (or other methods), and/or may have a comparatively lower silicon content in comparison to the first passivation layer 150-1. In some embodiments, the silicon content (or associated refractive index) of each of the passivation layers 150-1, 150-2, 150-3 may decrease with distance from the semiconductor surface 126S, defining a gradient in which passivation layers 150-1 closer to the semiconductor surface 126S may have higher silicon content or refractive indices as compared to passivation layers 150-2, 150-3 that are farther from the surface 126S.

As shown in FIG. 3B and FIG. 4, the multi-layer passivation stack 150s is patterned to form source contacts 115 and drain contacts 105 (block 410). For example, the multi-layer passivation stack 150s may be patterned to form openings which expose the surface 126S of the barrier layer 126 for placement of the source contact 115 and the drain contacts 105. The openings may be etched utilizing a patterned mask and a low-damage etch with respect to the barrier layer 126. Ohmic metal may be formed on the exposed portions of the barrier layer 126. However, it will be understood that in other embodiments the barrier layer 126 may also be recessed through the openings, and the source and drain contacts 115 and 105 may extend through the barrier layer 126. Suitable metals may include Ti, W, TiW, Si, TiWN, WSi, Re, Nb, Ni, Au, Al, Ta, Mo. NiSiₓ, TiSi, TiN, WSiN, Pt and the like. The ohmic metal may be annealed to provide the source contacts 115 and the drain contacts 105.

As shown in FIG. 3C and FIG. 4, the multi-layer passivation stack 150s is patterned to provide a gate opening 151, and to provide at least one additional opening 152 that exposes regions 126S2 of the semiconductor structure 190 (block 415). The openings 151, 152 may be formed before, after, or concurrently with forming the source and drain contacts 115 and 105. The gate opening(s) 151 may define trenches that extend in the Y-direction along the surface 126S. The opening(s) 152 may be formed between the gate opening 151 and the drain contact 105 (i.e., in the drain access region) and/or between the gate opening 151 and the source contact 115 (i.e., in the source access region; shown in phantom in FIG. 3C). The opening(s) 152 are laterally spaced apart from the gate opening 151 in the X-direction, and are adjacent to the drain contact 105 (and/or to the source contact 115).

In some embodiments, the opening(s) 152 in the multi-layer passivation stack 150s may be formed during the same etching process used to form the gate opening 151, or in a different etching process before or after forming the gate opening 151 and/or openings for the source and drain contacts 115 and 105. For example, in a GaN-based semiconductor structure 190 including a GaN channel layer 124 and an AlGaN barrier layer 126, during the etch used to form the gate opening 151, one or more additional openings 152 may be etched into the multi-layer passivation stack 150s to expose one or more regions 126S2 of the AlGaN barrier layer 126 between where the gate 110 is to be formed and where the drain contact 105 (and/or the source contact 115) is/are to be formed. As noted above, the removal of portions of the initial passivation layer 150-1 to form the openings or discontinuities 152 that expose regions 126S2 of the semiconductor surface 126S may reduce negative effects on current leakage and capacitance that may be created by deposition of the initial passivation layer 150-1 having higher silicon content.

As shown in FIG. 3D, a gate contact 110 may be formed within the gate opening 151, and may extend through the opening 151 to contact the exposed portion of the barrier layer 126. Suitable gate materials may include Ni, Pt, Ru, NiSiₓ, Au, Ti, Cu, Pd, Cr, TaN, W, and/or WSiN. The trench 151 (and thus the gate 110 therein) may extend in the Y-direction along the surface 126S. Also, portions or sidelobes of the gate 110 may laterally extend (e.g., in the X-direction) on the multi-layer passivation stack 150s. Though illustrated as being on the surface 126S of the barrier layer 126 in FIG. 3D, it will be understood that the source contacts 115, gate contacts 110, and/or drain contacts 105 may be formed within recesses in the surface 126S of the barrier layer 126 in some embodiments.

As shown in FIG. 3E and FIG. 4, a second passivation layer 155-1 is formed extending into the opening(s) 152 in the multi-layer passivation stack 150s and onto the surface 126S in a second region 126S2 of the semiconductor structure 190 between the first region 126S1 and the source 115 or drain contact 105 (block 420). The second passivation layer 155-1 may extend conformally along sidewalls of the opening 152 and onto the second region 126S2, or may substantially fill the opening 152.

The first passivation layer 150-1 is provided directly on region 126S1 of the semiconductor structure 190 adjacent the gate opening 151, while the second passivation layer 155-1 is provided directly on region 126S2 exposed by the opening 152, such that the first and second passivation layers 150-1, 155-1 extend along respective interfaces 126S1, 126S2 with the semiconductor structure 190. In the example of FIG. 3E, the respective interfaces 126S1, 126S2 are provided in the drain access region of the semiconductor structure 190 between the gate opening 151 and the drain contact 105, but may be similarly formed in the source access region between the gate opening 151 and the source contact 115 in some embodiments.

The second passivation layer 155-1 may have different electrical properties than the first passivation layer 150-1, and may be formed by similar or different methods. For example, the second passivation layer 155-1 may formed using a CVD process in some embodiments, or may be formed by a PVD process. In some embodiments, a first dielectric constant of the first passivation layer 150-1 may be greater than a second dielectric constant of the second passivation layer 155-1. For example, a first silicon content (or associated refractive index) of the first passivation layer 150-1 may be greater than a second silicon content (or associated refractive index) of the second passivation layer 155-1.

Still referring to FIG. 3E, one or more additional passivation layers 155-2 may also be formed on the second passivation layer 155-1 (e.g., filling the opening 152), so as to collectively form an additional multi-layer passivation stack 155s (also referred to as a second passivation layer stack 155s). The subsequently-formed passivation layer(s) 155-2 may be deposited using a PVD process (or other methods), and/or may have a comparatively lower dielectric constant or silicon content in comparison to the second passivation layer 155-1 (and in comparison to the first passivation layer 150-1). In some embodiments, the silicon content (or associated refractive index) of each of the passivation layers 155-1, 155-2 of the additional multi-layer passivation stack 155 may decrease with distance from the semiconductor surface 126S, such that the passivation layer 155-1 closer to the semiconductor surface 126S may have a higher silicon content or refractive index compared to passivation layer(s) 155-2 that are farther from the surface 126S.

As such, multiple passivation layers 150-1 and 155-1 may be formed on the surface 126S of the semiconductor structure 190, where the passivation layers 150-1 and 155-1 have different electrical properties and define respective interfaces 126S1 and 126S2 with the semiconductor structure 190. In addition (or alternatively), the sublayers of the multi-layer passivation stacks 150s, 155s may provide a gradient in electrical properties, with sublayers 150-1 and 155-1 that are closer to the surface 126S of the semiconductor structure 190 having higher dielectric constant, refractive index, and/or silicon content than sublayers 150-2, 150-3 and 155-2 that are farther from the surface 126S. That is, the electrical properties of the passivation layer stacks 150s, 155s may vary (i) along the surface 126S of the semiconductor structure 190 (e.g., using first and second passivation layers 150-1 and 155-1 having different silicon content), and (ii) in a direction away from (e.g., perpendicular to) the surface 126S of the semiconductor structure 190 (e.g., with higher silicon content layers 150-1 and 155-1 closer to the surface 126S and lower silicon content layers 150-2, 150-3 and 155-2 farther from the surface 126S).

As shown in FIG. 3F, a field plate 328 may be formed on the additional multi-layer passivation stack 155s, such that the second passivation layer stack 155s provides an IFPP layer between the field plate 328 and the first passivation layer stack 150s. Also, respective metal contacts 365 may be formed extending through openings in the interlayer passivation layer 155 to contact one or more of the contacts 105, 110, 115. For example, the interlayer passivation layer 155 may be patterned to form openings which expose the source contacts 115 and/or the drain contacts 105, and conductive metal may be formed on the exposed portions of the source contacts 115 and/or the drain contacts 105 to form the metal contacts 365. The metal contacts 365 may contain metal or other highly conductive material, including, for example, copper, cobalt, gold, and/or a composite metal. In the example of FIG. 3F, the metal contacts 365 are provided on the drain contact 105 and source contact 115, but it will be understood that the metal contacts 365 may be provided on all three terminals (i.e., source, gate, and drain) in some embodiments. An electrically insulating and/or passivating layer 360 (of similar or different composition than the passivation layers 150 and/or 155) may be formed on the metal contacts 365 as a final passivation layer, and may be patterned to define openings that expose the metal contacts 365 for electrical connections, e.g., input or and/or output connections to one or more external devices and/or for ground connections. The metal contacts 365 may thus define input (e.g., gate), output (e.g., drain), and/or ground (e.g., source) contact pads or terminals, which may be directly or indirectly connected to corresponding terminals (e.g., gate 110, drain 105, and source 115 terminals of a HEMT device) of the transistor structure 100.

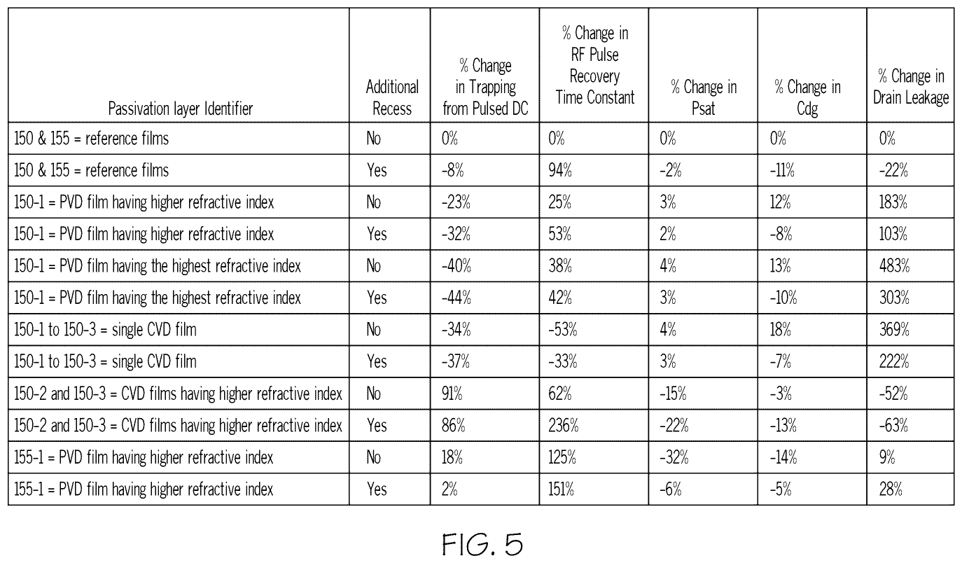

FIG. 5 is a table illustrating performance benefits of transistor structures including passivation layers according to some embodiments of the present disclosure. In particular, the data shown in FIG. 5, compares characteristics of transistor devices including modulated passivation layers with a single gate opening 151 (indicated as Additional Recess=No) with characteristics of transistor devices including modulated passivation layers having at least one additional opening 152 therein (indicated as Additional Recess =Yes) according to embodiments of the present disclosure. For each of these configurations (i.e., single opening 151 only; at least one additional opening 152), characteristics are shown for (i) a first passivation layer 150-1 and a second passivation layer 155-1 conventionally formed as PVD/CVD bilayers (indicated as reference films), (ii) the first passivation layer 150-1 having a higher RI/silicon content and deposited by PVD (by modifying the PVD portion of the PVD/CVD bilayer), (iii) the first passivation layer 150-1 having a highest RI/silicon content and deposited by PVD, (iv) the passivation layers 150-1, 150-2, 150-3 deposited by CVD (i.e., with no PVD layers, but with the similar total film thickness), (v) the passivation layers 150-2, 150-3 having higher RI/silicon content and deposited by CVD, and (vi) the second passivation layer 155-1 having a high RI/silicon content with IFPP deposited by PVD (by modifying the PVD portion of the PVD/CVD bilayer).

In particular, for the above-described configurations, FIG. 5 compares the change in trapping characteristics from pulsed DC, as well as the change in RF pulse recovery time constant. As shown in FIG. 5, by increasing the RI (e.g., the Si:N ratio) in the first passivation layer 150-1 that is in direct contact with the surface 126S of the barrier layer 126 (relative to overlying layers 150-2, 150-3 in the stack 150s), charge trapping can be reduced. Additionally or alternatively, using a CVD process (rather than PVD) to form the first passivation layer 150-1 may reduce both trapping and recovery time.

Also, FIG. 5 compares the change in measured drain leakage and gate-to-drain capacitance (Cdg) for the above-described configurations. In particular, FIG. 5 illustrates that the first passivation layer 150-1 with a single opening 151 (whether formed with increased silicon content or via a CVD process) may result in higher drain leakage and increased gate-to-drain capacitance, which is unfavorable for device performance and reliability. However, by disrupting the first passivation layer 150-1 with at least one additional opening or discontinuity 152, drain leakage and Cdg may be reduced (as compared to the single opening 151) in each of the illustrated configurations. FIG. 5 also compares the change in output power (Psat) for the above-described configurations, showing that reduction in leakage and Cdg by providing the first passivation layer 150-1 with at least one additional opening 152 may be achieved without sacrificing transient performance.

Further, FIG. 5 illustrates that when the same increase in RI/Si content is applied to passivation layers that do not directly contact surface 126S (e.g., passivation layers 150-2 and 150-3, which are farther from the surface 126S), the trapping and recovery time may be increased. Similarly, when the Si content of the second passivation layer 155-1 is increased without providing additional opening(s) 152 in the first passivation layer 150-1 (such that the second passivation layer 155-1 does not directly contact the surface 126S and is spaced apart therefrom), recovery time may be increased marginally. However, trapping may be significantly reduced by forming the additional opening(s) 152 in the first passivation layer 150-1 and forming the second passivation layer 155-1 directly on the surface 126S exposed by the opening(s) 152.

As shown in FIG. 5, increased trapping may correlate to lower output power, suggesting that the increased trap states of passivation layers with higher dielectric constants may be sufficient to suppress channel currents. In embodiments described herein, trapping can be reduced or minimized by providing direct contact between the higher dielectric constant or higher silicon content passivation layer 150-1 (and/or 155-1) and the surface 126S of the epitaxial layers 126, creating a path for trap dissipation.

Embodiments of the present disclosure may thereby provide multiple passivation layers having different electrical characteristics and respective interfaces with the semiconductor structure to provide local charge control in portions of the channel region between the gate and the drain (or source) regions. That is, embodiments of the present disclosure may modulate electrical properties of one or more passivation layers (for example, based on varying film composition, dielectric constant, refractive index, and/or point defects) along a surface of the semiconductor epitaxial structure and/or in a direction away from the surface so as to reduce charge trapping and achieve faster recover time or transient response.

Embodiments of the present disclosure may provide improved performance in RF devices. However, embodiments of the present disclosure are not limited to RF applications, and may be used in any DC device, including but not limited to Ka-band, MMIC, and power switch devices. For example, embodiments of the present disclosure may be used in applications with operating frequencies that range from less than about 4 GHz to Ka-Band designs (e.g., 26-40 GHz).

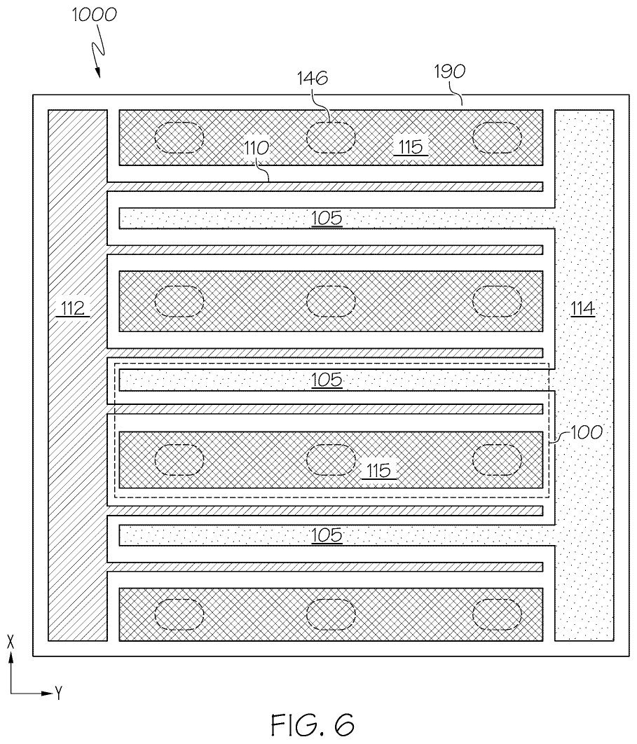

In some embodiments, as shown in FIG. 6, a transistor device or die 1000 may include multiple transistor structures 100 connected in parallel to device terminals or electrodes (e.g., an input terminal, an output terminal, and a ground terminal). For example, each of the gate 110, drain 105, and source 115 contacts may extend in a first direction (e.g., the Y-direction) to define gate, drain, and/or source ‘fingers’, which may be connected by one or more respective buses (e.g., by a gate bus and a drain bus on an upper surface 126A of the semiconductor structure 190. In FIG. 6, the gate fingers 110, drain fingers 105 and source fingers 115 may extend in parallel to each other, with the gate fingers 110 extending from the gate bus 112 in a first direction and the drain fingers 105 extending from the drain bus 114 in a direction opposite the first direction. Each gate finger 110 may be positioned between a drain finger 105 and a source finger 115 to define a unit cell 100. The gate fingers 110, drain fingers 105, and source fingers 315 (and connecting buses) may define part of gate-, drain-, and source-connected electrodes of the device, respectively, as defined by a top or frontside metallization structure. Dielectric layers that isolate the various conductive elements of the frontside metallization structure from each other are not shown in FIG. 6 to simplify the drawing. Since the gate fingers 110 are electrically connected to a common gate bus, the drain fingers 105 are electrically connected to a common drain bus, and the source fingers 115 are electrically connected together (e.g., through respective via openings 146 and a backside metal layer on the back surface of the substrate 122), it can be seen that the unit cell transistors 100 are electrically connected together in parallel.

One of the terminals of the device (e.g., a source terminal connected to the source contact(s) 115) may be configured to be coupled to a reference signal such as, for example, an electrical ground. In some embodiments, a conductive through substrate via connection or structure (e.g., a backside via opening formed through the back surface) may extend through the substrate 122 and epitaxial layer(s) 124, 126 to expose a portion of one of the contacts 105, 115, so as to allow for contact pads or terminals on the back side of the substrate (e.g., to couple the source contact 115 to ground). In other embodiments, a ground connection to one of the terminals device (e.g., the source terminal) may be provided outside the active area, e.g., in a peripheral area. In some embodiments, a backmetal layer on the back side of the substrate 122 may provide a backside ground plane, for example, in applications where proximity to ground may be desired.

While embodiments have been described herein with reference to particular HEMT structures, the present disclosure should not be construed as limited to such structures, and may be applied to formation of many different transistor structures, such as pHEMTs (including GaAs/AlGaAs pHEMTs) and/or GaN MESFETs.

The present disclosure is described with reference to the accompanying drawings, in which embodiments of the disclosure are shown. However, this disclosure should not be construed as limited to the embodiments set forth herein. Rather, these embodiments are provided so that this disclosure will be thorough and complete, and will fully convey the scope of the disclosure to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the disclosure herein is for the purpose of describing particular embodiments only and is not intended to be limiting of the disclosure. As used in the description and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the disclosure are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, embodiments of the present disclosure should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure.

Unless otherwise defined, all terms used in disclosing embodiments of the present disclosure, including technical and scientific terms, have the same meaning as commonly understood by one of ordinary skill in the art to which this disclosure belongs, and are not necessarily limited to the specific definitions known at the time of the present disclosure being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

In the drawings and specification, there have been disclosed typical embodiments of the invention, and, although specific terms have been employed, they have been used in a generic and descriptive sense only and not for purposes of limitation. The scope of the present disclosure is set forth by the following claims and their equivalents, and shall not be restricted or limited by the foregoing detailed description.

1. A transistor device, comprising:
a semiconductor structure;
a multi-layer passivation stack on the semiconductor structure;
source and drain contacts on the semiconductor structure; and
a gate on the semiconductor structure between the source and drain contacts,
wherein the multi-layer passivation stack comprises a plurality of passivation layers having different electrical properties and at least one opening extending therethrough that exposes a surface of the semiconductor structure between the gate and the source or drain contact.

2. The transistor device of claim 1, wherein the passivation layers comprise respective point defects, dielectric constants, refractive indices, and/or material compositions that differ from one another.

3. The transistor device of claim 1, wherein ones of the passivation layers that are closer to the surface of the semiconductor structure have a higher dielectric constant than ones of the passivation layers that are farther from the surface.

4. The transistor device of claim 1, wherein ones of the passivation layers that are closer to the surface of the semiconductor structure have a higher silicon content than ones of the passivation layers that are farther from the surface.

5. The transistor device of claim 1, wherein the passivation layers of the multi-layer passivation stack comprise a first passivation layer on a first region of the semiconductor structure adjacent the gate, and further comprising:
a second passivation layer that extends into the at least one opening in the multi-layer passivation stack and onto the surface in a second region of the semiconductor structure between the first region and the drain contact,
wherein the first and second passivation layers have different electrical properties and extend along respective interfaces with the first and second regions.

6. The transistor device of claim 5, wherein the respective interfaces extend along a drain access region of the semiconductor structure between the gate and the drain contact.

7. The transistor device of claim 6, wherein a first dielectric constant of the first passivation layer is greater than a second dielectric constant of the second passivation layer.

8. The transistor device of claim 6, wherein the first passivation layer and the second passivation layer comprise silicon, and wherein a first silicon content of the first passivation layer is greater than a second silicon content of the second passivation layer.

9. The transistor device of claim 7, wherein the second passivation layer is a sublayer of a second multi-layer passivation stack.

10. The transistor device of claim 6, wherein a source access region of the semiconductor structure between the gate and the source contact is free of an interface with the second passivation layer.

11. The transistor device of claim 1, wherein the semiconductor structure comprises a channel layer and a barrier layer defining a heterojunction therebetween.

12. A transistor device, comprising:
a semiconductor structure;
source and drain contacts on the semiconductor structure;
a gate on the semiconductor structure between the source and drain contacts; and
first and second passivation layers on a surface of the semiconductor structure between the gate and the source or drain contact, the first and second passivation layers having different electrical properties and extending along respective interfaces with the semiconductor structure.

13. The transistor device of claim 12, wherein the first passivation layer is on a first region of the surface adjacent the gate and comprises at least one opening therein that exposes a second region of the surface, and the second passivation layer extends into the at least one opening and onto the second region.

14. (canceled)

15. (canceled)

16. The transistor device of claim 12, wherein at least one of the first passivation layer or the second passivation layer is a sublayer of a multi-layer passivation stack comprising a plurality of stacked passivation layers having different electrical properties.

17. The transistor device of claim 16, wherein ones of the stacked passivation layers that are closer to the surface of the semiconductor structure have a higher dielectric constant than ones of the stacked passivation layers that are farther from the surface.

18.-20. (canceled)

21. A method of fabricating a transistor device, the method comprising:
forming a multi-layer passivation stack on a semiconductor structure, the multi-layer passivation stack comprising a plurality of passivation layers having different electrical properties;
forming source and drain contacts on the semiconductor structure;
forming a gate opening in the multi-layer passivation stack; and
forming at least one additional opening in the multi-layer passivation stack that exposes a surface of the semiconductor structure between the gate opening and the source or drain contact.

22. (canceled)

23. The method of claim 21, wherein ones of the passivation layers that are closer to the surface of the semiconductor structure have a higher dielectric constant than ones of the passivation layers that are farther from the surface.

24. (canceled)

25. The method of claim 21, wherein forming the multi-layer passivation stack comprises:
forming a first passivation layer of the plurality of passivation layers on the surface of the semiconductor structure using a chemical vapor deposition process; and
forming at least one subsequent passivation layer of the plurality of passivation layers using a physical vapor deposition process.

26. The method of claim 21, wherein the passivation layers of the multi-layer passivation stack comprise a first passivation layer on a first region of the semiconductor structure adjacent the gate opening, and further comprising:
forming a second passivation layer that extends into the at least one additional opening in the multi-layer passivation stack and onto the surface in a second region of the semiconductor structure between the first region and the source or drain contact,
wherein the first and second passivation layers have different electrical properties and extend along respective interfaces with the first and second regions.

27. (canceled)

28. (canceled)

29. The method of claim 26, wherein forming the second passivation layers is performed using a chemical vapor deposition process.

30. (canceled)

31. The method of claim 26, wherein the first passivation layer and the second passivation layer comprise silicon, and wherein a first silicon content of the first passivation layer is greater than a second silicon content of the second passivation layer.
